(19) United States
(12) Patent Application Publication
(10) Pub. No.: US 2012/0057399 A1
(43) Pub. Date: Mar. 8, 2012

(54) ASYMMETRIC VIRTUAL-GROUND SINGLE-ENDED SRAM AND SYSTEM THEREOF

(76) Inventors: Shyh-Jye JOU, Hsinchu County (TW); Jhih-Yu Lin, Taichung City (TW); Ching-Te Chuang, Taipei County (TW); Ming-Hsien Tu, Tainan City (TW); Ming-Chien Tsai, Kaohsiung County (TW)

(21) Appl. No.: 12/876,682

(22) Filed: Sep. 7, 2010

(51) Int. Cl. G11C 11/00

(52) U.S. Cl. 365/156

(57) ABSTRACT

The present invention discloses an asymmetric virtual-ground single-ended SRAM and a system thereof, wherein a first inverter is coupled to a high potential and a virtual ground, and wherein the first inverter and a second inverter form a latch loop, and wherein a third inverter is electrically connected with the second inverter, and wherein the third inverter and the second inverter are jointly coupled to the high potential and a ground. A write word line and a read word line control an access transistor and a pass transistor to undertake writing and reading of signals. A plurality of asymmetric virtual-ground single-ended SRAMs forms a memory system.

### BACKGROUND OF THE INVENTION

1. Field of the Invention

The present invention relates to a SRAM structure, particularly to an asymmetric virtual-ground single-ended SRAM and a system thereof, wherein WSNM is increased without affecting the threshold voltage and turn-on voltage.

2. Description of the Related Art

The capacity of a memory has been greatly increased with the advance of the semiconductor technology. To achieve low voltage, low power consumption, small volume and high speed, SRAM (Static Random Access Memory) usually adopts a single bit line design to write and read. However, the single bit line design has the problems of writing “1” error and large power consumption.

Refer to FIG. 1(a) a diagram schematically showing the circuit architecture of a conventional common-ground single-ended SRAM cell. When “0” is to be written into the common-ground single-ended SRAM cell 50 from a bit line 54, a write word line 58 controls an access transistor 52 to offer strong pull-down strength to a pull-down transistor 56 to complete writing “0”. In the low-voltage design, the Q point suffers threshold voltage loss through the pull-down transistor 56. The Q point potential is further weakened by the voltage dividing effect between the access transistor 52 and the pull-down transistor 56. Thus, writing “1” into the SRAM cell 50 from the bit line 54 is likely to fail because of the abnormal Q point potential. Besides, the common-ground single-ended SRAM cell 50 has greater power consumption because the incomplete turn-off in the state change of the inverter causes greater static current.

To solve the abovementioned problems, a virtual ground design is used to prevent from signal attenuation and greater static current. Refer to FIG. 1(b) a diagram schematically showing the circuit architecture of a conventional common virtual-ground single-ended SRAM cell. The common virtual-ground single-ended SRAM cell 60 is different from the common-ground single-ended SRAM cell 50 of FIG. 1(b) in that a virtual ground VGND is used to cut off the path of direct current and reduce power consumption. Further, the voltage dividing effect between the access transistor 62 and the pull-down transistor 66 is reduced when the write word line 68 controls the access transistor 62 to turn on and write “1” of the bit line 64. However, the virtual ground VGND reduces the voltage V_{GS} across the gate and source of the n-type transistor of the left inverter. Besides, the body effect impairs the writing operation of the SRAM cell 60 because the body effect increases the threshold voltage and turn-on voltage of the left inverter.

Accordingly, the present invention proposes an asymmetric virtual-ground single-ended SRAM and a system thereof to overcome the abovementioned problems, wherein an asymmetric virtual-ground design is used to increase the write/read speed of SRAM, decrease power consumption and achieve a better SNM (Static Noise Margin).

### SUMMARY OF THE INVENTION

The primary objective of the present invention is to provide an asymmetric virtual-ground single-ended SRAM and a system thereof, wherein asymmetric virtual ground is used to improve signal weakening when “1” is written into a single-ended SRAM, whereby the single-ended SRAM can apply to a lower-voltage environment and achieve a better WSNM (Write Static Noise Margin).

Another objective of the present invention is to provide an asymmetric virtual-ground single-ended SRAM and a system thereof, wherein the threshold voltage does not increase with the body effect, whereby the turn-on voltage of the inverter set of the latch loop doses not increase, and whereby the single-ended SRAM can achieve a fast write/read speed.

A further objective of the present invention is to provide an asymmetric virtual-ground single-ended SRAM and a system thereof, wherein leakage current is effectively reduced when the inverter set of the latch loop is switching, whereby the power consumption of the single-ended SRAM is greatly reduced.

To achieve the abovementioned objectives, the present invention proposes an asymmetric virtual-ground single-ended SRAM, which comprises a first inverter, a second inverter, a third inverter, an access transistor and a pass transistor. The first inverter and the second inverter are electrically connected crosswise to form a latch loop. The first inverter is coupled to a high potential and a virtual ground. The second inverter is coupled to the high potential and a ground. The third inverter is coupled to the high potential and the ground and electrically connected with the second inverter. The access transistor and the pass transistor are respectively electrically connected with the first inverter and the third inverter. A write word line controls the access transistor to perform a writing activity to transfer a signal from a bit line to the latch loop. A read word line controls the pass transistor to perform a reading activity to transfer a signal to the bit line from the latch loop.

The present invention further proposes an asymmetric virtual-ground single-ended SRAM system, which comprises a plurality of asymmetric virtual-ground single-ended SRAMs, at least one bit line, at least one write word line and at least one read word line. Each asymmetric virtual-ground single-ended SRAM is electrically connected with at least one virtual ground. At least one bit line is electrically connected with the asymmetric virtual-ground single-ended SRAMs. The plurality of asymmetric virtual-ground single-ended SRAMs is controlled by at least one write word line to transfer signals from the bit lines to the asymmetric virtual-ground single-ended SRAMs. The plurality of asymmetric virtual-ground single-ended SRAMs is also controlled by at least one read word line to transfer signals to the bit lines from the asymmetric virtual-ground single-ended SRAMs.

Below, the embodiments are described in detail in cooperation with the attached drawings to make easily understood the objectives, technical contents, characteristics and accomplishments of the present invention.

### BRIEF DESCRIPTION OF THE DRAWINGS

FIG. 1(a) is a diagram schematically showing the circuit architecture of a conventional common-ground single-ended SRAM cell;

FIG. 1(b) is a diagram schematically showing the circuit architecture of a conventional common virtual-ground single-ended SRAM cell;

FIG. 2 is a diagram schematically showing the circuit architecture of an asymmetric virtual-ground single-ended SRAM according to the present invention;

FIG. 3 is a diagram showing the voltage transfer curves of a conventional single-ended SRAM and an asymmetric virtual-ground single-ended SRAM of the present invention;

FIG. 4 is a diagram schematically showing the circuit architecture of an asymmetric virtual-ground single-ended SRAM system according to the present invention; and

FIG. 5 is a diagram schematically showing the circuit architecture of a positive feedback sensing keeper of an asymmetric virtual-ground single-ended SRAM according to the present invention.

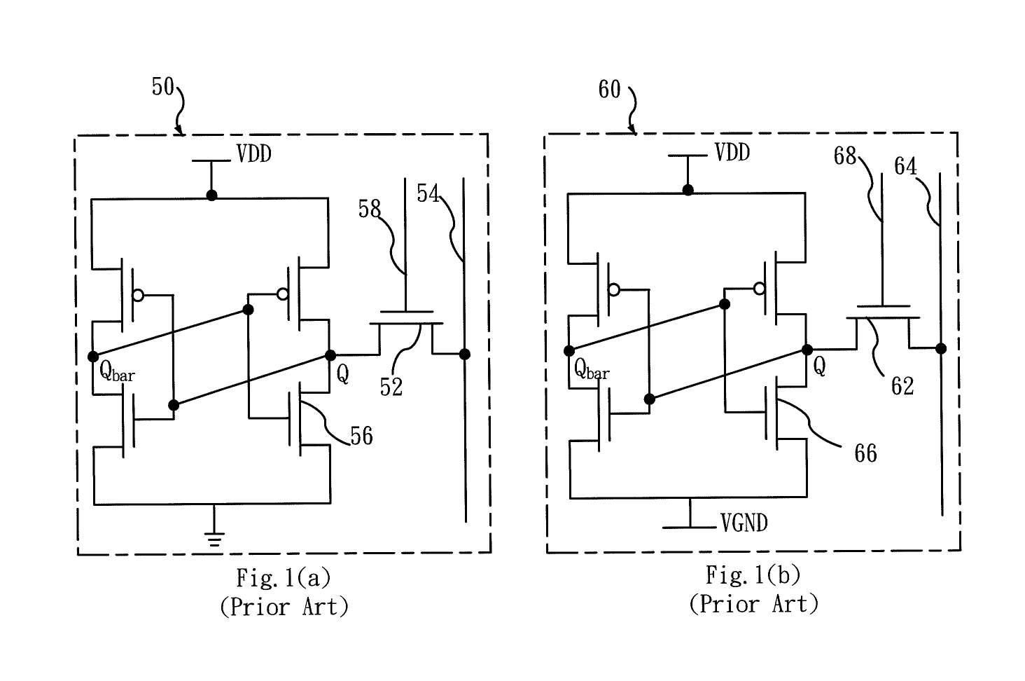

### DETAILED DESCRIPTION OF THE INVENTION

The present invention proposes an asymmetric virtual-ground single-ended SRAM and a system thereof, wherein asymmetric virtual ground is used to improve signal weakening without affecting the threshold voltage and turn-on voltage when “1” is written into a single-ended SRAM, whereby the power consumption of the single-ended SRAM is effectively reduced, and whereby the write/read speed of SRAM is greatly increased. Below, the embodiments are described in detail to demonstrate the technical contents of the present invention.

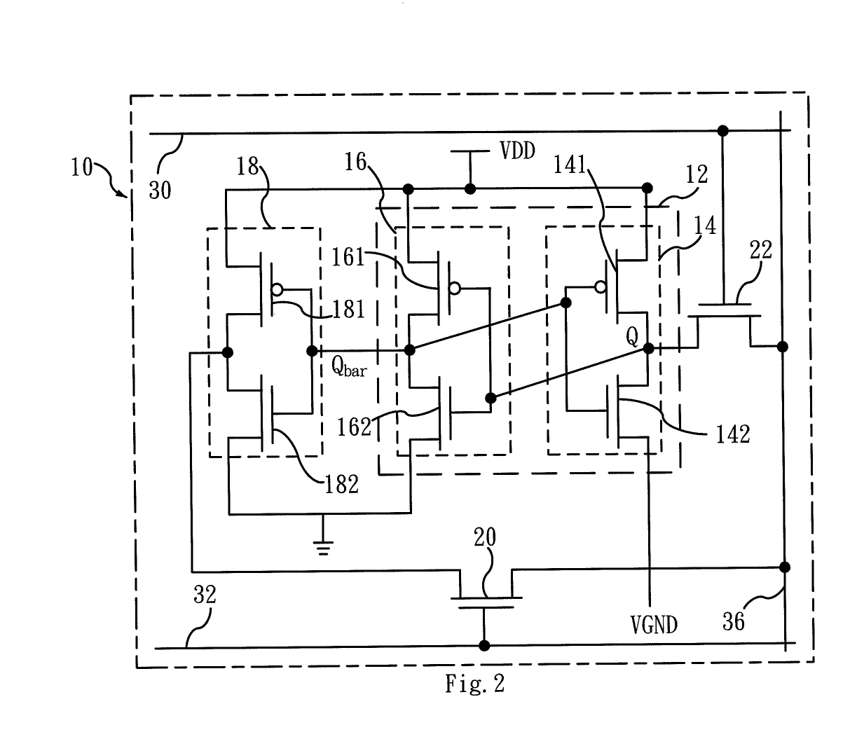

Refer to FIG. 2 a diagram schematically showing the circuit architecture of an asymmetric virtual-ground single-ended SRAM according to the present invention. The asymmetric virtual-ground single-ended SRAM 10 of the present invention comprises a first inverter 14, a second inverter 16, a third inverter 18, a pass transistor 20 and an access transistor 22, wherein a write word line 30, a read word line 32 and a bit line 36 are respectively electrically connected with the pass transistor 20 and the access transistor 22.

The first inverter 14 includes a first p-type transistor 141 and a first n-type transistor 142. The gate of the first p-type transistor 141 is electrically connected with the gate of the first n-type transistor 142. The drain of the first p-type transistor 141 is electrically connected with the drain of the n-type transistor 142 with the joint node being a Q point. The access transistor 22 is electrically connected with the Q point. The source of the first p-type transistor 141 is coupled to a high potential VDD. The source of the first n-type transistor 142 is coupled to a virtual ground VGND.

The second inverter 16 includes a second p-type transistor 161 and a second n-type transistor 162. The gate of the second p-type transistor 161 is electrically connected with the gate of the second n-type transistor 162. The gates of the second p-type and n-type transistors 161 and 162 are electrically connected with the Q point. The drain of the second p-type transistor 161 is electrically connected with the drain of the second n-type transistor 162 with the joint point being a Q_{bar} point. The Q_{bar} point is electrically connected with the gates of the first p-type and n-type transistors 141 and 142, whereby the first and second inverters 14 and 16 form a latch loop 12. The source of the second p-type transistor 161 is coupled to the high potential VDD. The source of the second n-type transistor 162 is coupled to a ground.

The third inverter 18 includes a third p-type transistor 181 and a third n-type transistor 182. The drain of the third p-type transistor 181 is electrically connected with the drain of the third n-type transistor 182. The drains of the third p-type and n-type transistors 181 and 182 are electrically connected with the pass transistor 20. The gate of the third p-type transistor 181 is electrically connected with the gate of the n-type transistor 182. The gates of the third p-type and n-type transistors 181 and 182 are electrically connected with the drains of the second p-type and n-type transistors 161 and 162. The source of the third p-type transistor 181 is coupled to the high potential VDD. The source of the third n-type transistor 182 is coupled to the ground.

Above has been described the circuit architecture of the asymmetric virtual-ground single-ended SRAM of the present invention, wherein only the first inverter 14 is coupled to the virtual ground VGND with the second and third inverters 16 and 18 remaining coupled to the ground. Below will be described the response in the case that only the first inverter 14 is coupled to the virtual ground VGND.

To improve the problem that the signal “1” is weakened when the signal “1” is written into a single-ended SRAM and the problem that the threshold voltage and turn-on voltage of the second inverter are increased, the first inverter 14 is coupled to the virtual ground VGND floatingly when the signal “1” of the bit line is written into the single-ended SRAM. However, the first inverter 14 is still coupled to the ground in other cases. When the signal “1” is to be written into the single-ended SRAM, the write word line 30 controls the access transistor 22 to turn on in order to write the signal “1” into the single-ended SRAM. At this time is reduced the signal weakening caused by the voltage dividing effect of the first n-type transistor 142 and the access transistor 22 because only the source of the first n-type transistor 142 of the first inverter 14 is coupled to the virtual ground VGND. Meanwhile, the turn-on voltage of the second inverter 16 does not increase because the body effect does not increase the threshold voltage of the n-type transistor 162 of the second inverter 16. In other words, asymmetric virtual ground VGND can eliminate signal “1” weakening at the Q point without increasing the threshold voltage of the second inverter 16.

When the signal “0” is to be written into the single-ended SRAM, the write word line 30 controls the access transistor 22 to turn on in order to write the signal “0” into the single-ended SRAM. The signal “0” pulls down the Q point to change the storage state of the Q_{bar} point of the second inverter 16. The latch loop 12 is shut off because the source of the first n-type transistor 142 of the first inverter 14 is coupled to the virtual ground VGND, but the operation of writing “0” is not affected by it. Shifting the virtual ground VGND to the ground will further favor the operation of writing “0”.

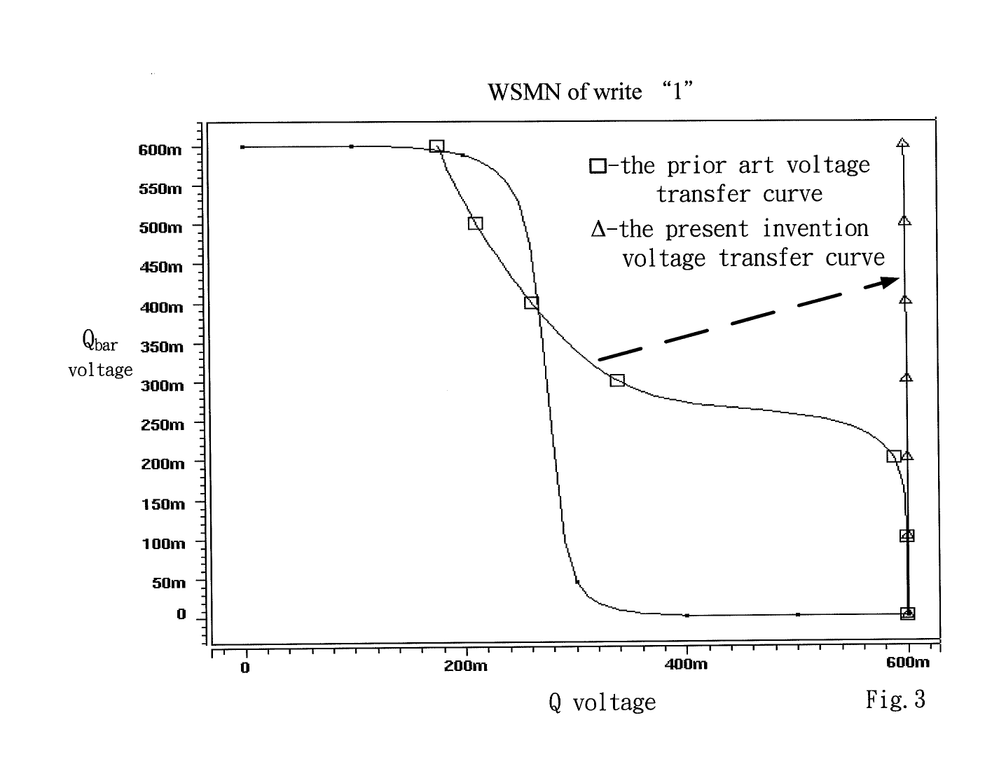

Refer to FIG. 3 a diagram showing the voltage transfer curves of a conventional single-ended SRAM and an asymmetric virtual-ground single-ended SRAM of the present invention. As the source of the first n-type transistor 142 is coupled to the virtual ground VGND floatingly, the voltage transfer curve of the first inverter 14 is a straight line at the high potential VDD. It means: Although the supply voltage is very low (0.6V), the asymmetric virtual ground can increase the WSNM (Write Static Noise Margin) in writing “1”. Thus is greatly increased the range of noise tolerance.

Above has been described the response in the case that the asymmetric virtual-ground single-ended SRAM 10 is coupled to the virtual ground VGND. Below will be described a system containing a plurality of asymmetric virtual-ground single-ended SRAMs 10.

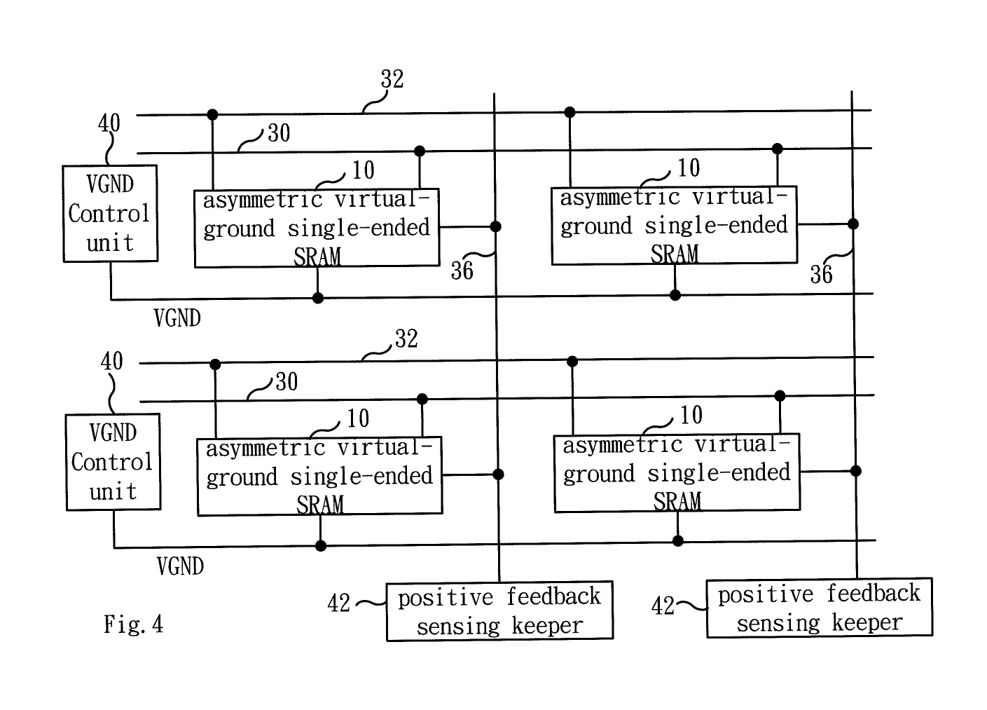

Refer to FIG. 4, and refer to FIG. 2 again. A plurality of asymmetric virtual-ground single-ended SRAMs 10 is respectively electrically connected with the write word lines 30, the read word lines 32, the virtual ground VGND and the bit lines 36. The write word lines 30 enable the writing activities to transfer signals from the bit lines 36 to the asymmetric virtual-ground single-ended SRAMs 10. The read word lines 32 enable the reading activities to transfer signals to the bit lines 36 from the asymmetric virtual-ground single-ended SRAMs 10.

The virtual ground VGND is controlled by a virtual-ground control unit 40. The virtual-ground control unit 40 is electrically connected with said virtual ground utilizing a row-based connection, a column-based connection or a block-based connection. Thereby, the virtual-ground control unit 40 controls the asymmetric virtual-ground single-ended SRAM 10 to floatingly connect with the virtual ground VGND when a signal is written into the asymmetric virtual-ground single-ended SRAM 10, and controls the asymmetric virtual-ground single-ended SRAM 10 to connect with the ground when a non-writing activity is undertaken.

While the read word line 32 controls an activity of reading a signal “1” from the asymmetric virtual-ground single-ended SRAM 10, the third inverter 18 charges the bit line 36. The charging path is controlled by the pass transistor 20. Thus, the read signal “1” is weakened, and the missing rate of reading “1” is increased. Therefore, a positive feedback sensing keeper 42 is arranged in the memory system and electrically connected with the bit lines 36 to maintain the read signal “1” at a high potential, improve the problem of signal weakening, increase reading speed, and decrease power consumption caused by current leakage. Below is to be described the circuit architecture of the positive feedback sensing keeper 42.

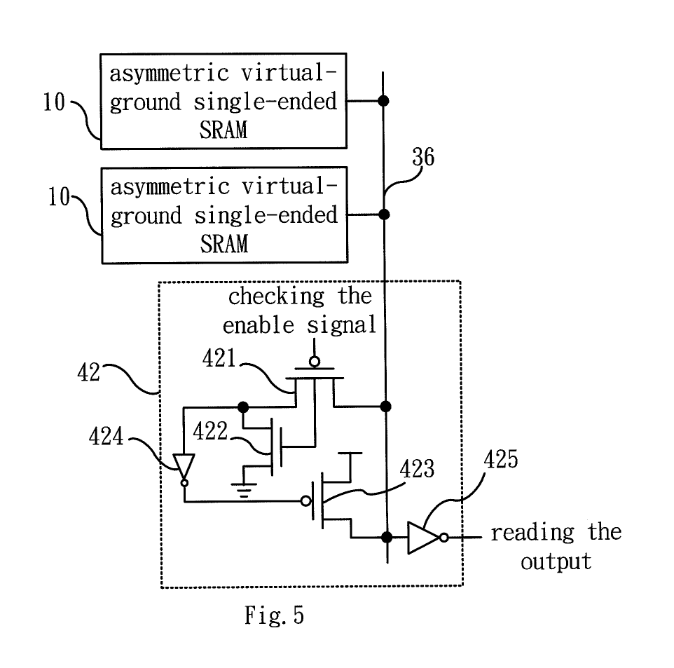

Refer to FIG. 5 a diagram schematically showing the circuit architecture of a positive feedback sensing keeper of an asymmetric virtual-ground single-ended SRAM according to the present invention. The positive feedback sensing keeper 42 further comprises an enable transistor 421, a first switch transistor 422, a second switch transistor 423, an inverter 424 and a reading buffer 425. When the enable signal is “1”, the first switch transistor 422 is turned on, and the inverter 424 transfers the signal “1” to turn off the second switch transistor 423. In such a case, the bit line 36 is not affected. When a signal is read from the asymmetric virtual-ground single-ended SRAM 10, the enable signal is “0” and turns on the enable transistor 421 to sense the signal of the bit line 36. When the signal “0” stored in the bit line 36 is read, the inverter 424 turns off the second switch transistor 423. Thus, the positive feedback sensing keeper 42 would not pull down the signal of the bit line 36. When the signal stored in the bit line 36 is “1”, the inverter 424 turns on the second switch transistor 423, and the second switch transistor 423 pulls up the signal “1” of the bit line 36 to a level satisfying the standard of a high potential. The signal “0” or “1” read from the asymmetric virtual-ground single-ended SRAM 10 is stored in the bit line 36 and output by the reading buffer 425.

From the above description, it is known that the asymmetric virtual ground design of the present invention can effectively solve the bottleneck of the conventional technology, whereby the single-ended SRAM can operate at a lower voltage, having advantages of better SNM, lower power consumption and higher read/write speed. Therefore, the present invention can apply to system chip designs and integrate with various electronic devices.

The embodiments described above are only to demonstrate the technical contents and characteristics of the present invention to enable the persons skilled in the art to understand, make, and use the present invention. However, it is not intended to limit the scope of the present invention. Any equivalent modification or variation according to the spirit of the present invention is to be also included within the scope of the present invention.

What is claimed is:

1. An asymmetric virtual-ground single-ended static random access memory comprising
a first inverter coupled to a high potential and a virtual ground;
a second inverter crosswise electrically connected with said first inverter to form a latch loop and coupled to said high potential and a ground;
a third inverter electrically connected with said second inverter and coupled to said high potential and said ground;
an access transistor electrically connected with said first inverter, a write word line and a bit line, wherein said write word line controls said access transistor to perform a writing activity to transfer a signal from said bit line to said latch loop; and
a pass transistor electrically connected with said third inverter, a read word line and said bit line, wherein said read word line controls said pass transistor to perform a reading activity to transfer a signal from said latch loop to said bit line.

2. The asymmetric virtual-ground single-ended static random access memory according to claim 1, wherein said first inverter further comprises
a first p-type transistor, wherein a source of said first p-type transistor is coupled to said high potential; and
a first n-type transistor, wherein a gate of said first n-type transistor is electrically connected with a gate of said first p-type transistor, and wherein a drain of said first n-type transistor is electrically connected with a drain of said first p-type transistor and said access transistor, and wherein a source of said first n-type transistor is coupled to said virtual ground.

3. The asymmetric virtual-ground single-ended static random access memory according to claim 2, wherein said second inverter further comprises
a second p-type transistor, wherein a source of said second p-type transistor is coupled to said high potential; and
a second n-type transistor, wherein a gate of said second n-type transistor is electrically connected with a gate of said second p-type transistor, said drain of said first n-type transistor and said drain of said first p-type transistor, and wherein a drain of said second n-type transistor is electrically connected with a drain of said second p-type transistor, said gate of said first n-type transistor and said gate of said first p-type transistor, and wherein a source of said second n-type transistor is coupled to said ground.

4. The asymmetric virtual-ground single-ended static random access memory according to claim 3, wherein said third inverter further comprises
a third p-type transistor, wherein a source of said third p-type transistor is coupled to said high potential; and
a third n-type transistor, wherein a drain of said third n-type transistor is electrically connected a drain of said third p-type transistor and said pass transistor, and wherein a gate of said third n-type transistor is electrically connected with a gate of said third p-type transistor, said drain of said second n-type transistor and said drain of said second p-type transistor, and wherein a source of said third n-type transistor is coupled to said ground.

5. An asymmetric virtual-ground single-ended static random access memory system comprising
a plurality of asymmetric virtual-ground single-ended static random access memories each electrically connected with at least one virtual ground;
at least one bit line electrically connected with said asymmetric virtual-ground single-ended static random access memories;
at least one write word line electrically connected with said asymmetric virtual-ground single-ended static random access memories, and enabling a writing activity to transfer a signal from said bit line to one said asymmetric virtual-ground single-ended static random access memory; and
at least one read word line electrically connected with said asymmetric virtual-ground single-ended static random access memories, and enabling a reading activity to transfer a signal to said bit line from one said asymmetric virtual-ground single-ended static random access memory.

6. The asymmetric virtual-ground single-ended static random access memory system according to claim 5 further comprising at least one virtual-ground control unit electrically connected with said virtual ground and enabling a floating connection with said virtual ground.

7. The asymmetric virtual-ground single-ended static random access memory system according to claim 6 wherein said virtual-ground control unit electrically connected with said virtual ground utilizing a row-based connection, a column-based connection or a block-based connection.

8. The asymmetric virtual-ground single-ended static random access memory system according to claim 5 further comprising at least one positive feedback sensing keeper electrically connected with said bit line and maintaining a read signal at a high potential.

9. The asymmetric virtual-ground single-ended static random access memory system according to claim 5, wherein said asymmetric virtual-ground single-ended static random access memories are coupled to a high potential and a ground.
